(19) United States
(12) Patent Application Publication
(10) Pub. No.: US 2018/0204729 A1
(43) Pub. Date: Jul. 19, 2018

(54) SUBSTRATE PROCESSING METHOD AND SUBSTRATE PROCESSING DEVICE

(71) Applicant: ULVAC, INC., Kanagawa (JP)

(72) Inventors: Kazuhiro SONODA, Chigasaki-shi (JP); Yutaka KOKAZE, Chigasaki-shi (JP); Ryosuke FUKAYA, Chigasaki-shi (JP); Katsuaki NAKANO, Chigasaki-shi (JP)

(21) Appl. No.: 15/748,574

(22) PCT Filed: Jul. 28, 2016
(86) PCT No.: PCT/JP2016/072179

§ 371 Date: Jan. 29, 2018

(30) Foreign Application Priority Data
Aug. 17, 2015 (JP) 2015-160492

(51) Int. Cl. H01L 21/3065; H01L 21/304; H01L 21/768; H01L 21/687

(52) U.S. Cl. CPC H01L 21/3065; H01L 21/304; H01J 2237/3341; H01L 21/68714; H01L 21/768

(57) ABSTRACT

A substrate processing device including an accommodation unit that accommodates a substrate. A gas supply unit supplies plasma generation gas. A plasma supply unit generates plasma from the plasma generation gas supplied by the gas supply unit and supplies the plasma to the accommodation unit. The plasma generation gas is a gas mixture of hydrogen gas and an additive gas or a gas combining the gas mixture and a rare gas. The additive gas includes at least either one of nitrogen atoms and oxygen atoms. The gas supply unit is configured to supply the plasma supply unit with the plasma generation gas so that a flow ratio that is a ratio of a flow of the additive gas relative to a flow of the hydrogen gas is 1/500 or greater.

### RELATED APPLICATIONS

The present application is a National Phase entry of PCT Application No. PCT/JP2016/072179, filed Jul. 28, 2016, which claims priority from Japanese Patent Application No. 2015-160492, filed Aug. 17, 2015, the disclosures of which are hereby incorporated by reference herein in their entirety.

### TECHNICAL FIELD

The present invention relates to a substrate processing method and a substrate processing device that reduce an oxide film formed on a surface of a substrate.

### BACKGROUND ART

A known method uses plasma of a gas mixture including a hydrogen-containing gas and helium to reduce an oxide film formed on the surface of a metal film that is exposed from a contact hole or the like. In this method, the oxide film is reduced when the oxygen included in the oxide film reacts with the hydrogen ions and hydrogen radicals included in the plasma (refer to, for example, patent document 1).

Patent Document 1: Japanese Laid-Open Patent Publication No. 2001-203194

### SUMMARY OF THE INVENTION

In the method described above, there is a demand for an increase in the reduction speed of the oxide film per consumed power that is required to generate the plasma.

It is an object of the present invention to provide a substrate processing method and a substrate processing device that increases the reduction speed of an oxide film per consumed power.

In one aspect, a substrate processing method includes generating a gas mixture by mixing hydrogen gas and an additive gas, generating plasma from the gas mixture or a gas combining the gas mixture and a rare gas, and reducing an oxide film formed on the substrate with the plasma. The additive gas includes at least either one of nitrogen atoms and oxygen atoms. The generation of a gas mixture includes mixing the additive gas and the hydrogen gas so that a flow ratio that is a ratio of a flow of the additive gas relative to a flow of the hydrogen gas is 1/500 or greater.

In one aspect, a substrate processing device includes an accommodation unit that accommodates a substrate, a gas supply unit that supplies plasma generation gas, and a plasma supply unit that generates plasma from the plasma generation gas supplied by the gas supply unit and supplies the plasma to the accommodation unit. The plasma generation gas is a gas mixture of hydrogen gas and an additive gas or a gas combining the gas mixture and a rare gas. The additive gas includes at least either one of nitrogen atoms and oxygen atoms. The gas supply unit supplies the plasma supply unit with the plasma generation gas so that a flow ratio that is a ratio of a flow of the additive gas relative to a flow of the hydrogen gas is 1/500 or greater.

In the above-described method and device, in contrast with when plasma is generated from only hydrogen gas or a gas combining hydrogen gas and a rare gas, the generation of plasma from a gas mixture of hydrogen gas and an additive gas limits the deactivation of active species, which is generated from the hydrogen gas, with the additive gas. This increases the ratio of the active species that reach the oxide film in the active species generated from the hydrogen gas. As a result, the reduction speed pf the oxide film per consumed power is increased.

In one embodiment, the additive gas is oxygen gas. Preferably, the flow ratio is set to 1/10 or less.

In this method, deactivation of active species is limited. Further, the oxygen in the plasma that remains in the substrate is limited.

In one embodiment, the additive gas is nitrogen gas. Preferably, the flow ratio is set to 1/10 or less.

In this method, deactivation of active species is limited. Further, the nitrogen in the plasma that remains in the substrate is limited.

In one embodiment, in the substrate processing method, the reduction of an oxide film includes using the plasma as first plasma to reduce the oxide film. The method may further include generating second plasma from the hydrogen gas or a gas combining the hydrogen gas and the rare gas by stopping supply of the additive gas after reducing the oxide film with the first plasma, and applying the second plasma to the substrate.

Further, in one embodiment, in the substrate processing device, the gas supply unit is capable of supplying the plasma generation gas as a first plasma generation gas and capable of supplying the hydrogen gas or a gas combining the hydrogen gas and the rare gas as a second plasma generation gas. The device further includes a control unit configured to control the plasma supply unit and the gas supply unit so as to execute processes including supplying the first plasma generation gas from the gas supply unit to the plasma supply unit, generating first plasma from the first plasma generation gas with the plasma supply unit and supplying the first plasma to the accommodation unit, supplying the second plasma generation gas from the gas supply unit to the plasma supply unit by stopping supply of the additive gas after supplying the first plasma to the accommodation unit, and generating second plasma from the second plasma generation gas with the plasma supply unit and supplying the second plasma to the accommodation unit.

In the above method and device, after reducing the oxide film with the first plasma, at least either one of the oxygen atoms and nitrogen atoms remaining in the substrate may be removed by using the second plasma to process the substrate.

### BRIEF DESCRIPTION OF THE DRAWINGS

FIG. 1 is a schematic block diagram illustrating a substrate processing device according to one embodiment of the present invention.

FIG. 2 is a graph illustrating changes in the reflectivity of a copper film and the reduction rate when reducing an oxide film on a copper film surface with hydrogen gas.

FIG. 3 is a graph illustrating changes in the reflectivity of the copper film and the reduction rate when reducing the oxide film on the copper film surface with a first plasma generation gas that includes nitrogen gas as an additive gas.

FIG. 4 is a graph illustrating changes in the reflectivity of the copper film and the reduction rate of the copper film when reducing the oxide film on the copper film surface with the first plasma generation gas that includes oxygen gas as an additive gas.

FIG. 5 is a graph illustrating the relationship between the luminescence spectrum and luminescence intensity of the hydrogen plasma.

FIG. 6 is a graph illustrating the result of a surface analysis conducted through SIMS on an analysis substrate of test example 4.

FIG. 7 is a graph illustrating the result of a surface analysis conducted through SIMS on an analysis substrate of test example 5.

FIG. 8 is a graph illustrating the result of a surface analysis conducted through SIMS on an analysis substrate of test example 6.

FIG. 9 is a graph illustrating the result of a surface analysis conducted through SIMS on an analysis substrate of test example 7.

FIG. 10 is a graph illustrating the result of a surface analysis conducted through SIMS on an analysis substrate of test example 8.

### DESCRIPTION OF THE EMBODIMENTS

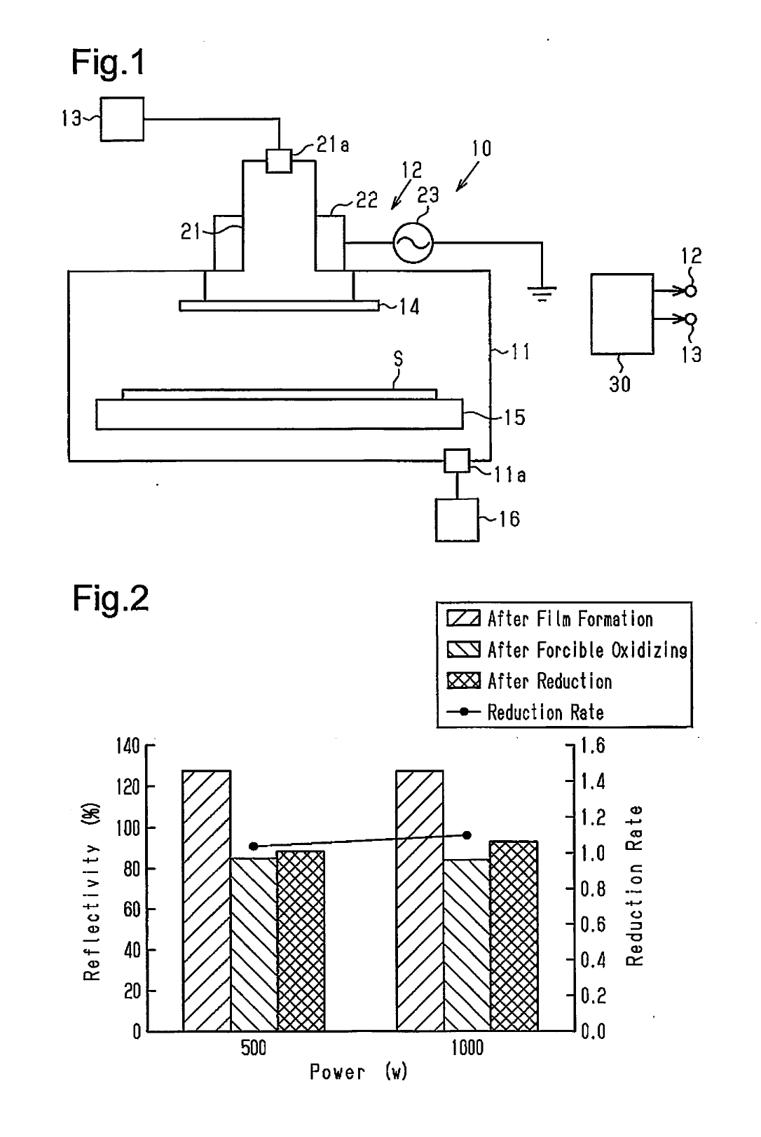

One embodiment of a substrate processing method and a substrate processing device will now be described with reference to FIGS. 1 to 10. In the description hereafter, the configuration of the substrate processing device, the substrate processing method, and examples will be described in order.

[Configuration of Substrate Processing Device]

The configuration of the substrate processing device will now be described with reference to FIG. 1.

As illustrated in FIG. 1, a substrate processing device 10 includes an accommodation unit 11 that accommodates the substrate S, a plasma supply unit 12 that supplies plasma to the accommodation unit 11, and a gas supply unit 13 that supplies gas to the plasma supply unit 12.

The gas supply unit 13 supplies plasma generation gas to the plasma supply unit 12. The plasma generation gas is a gas mixture or a gas combining the gas mixture and a rare gas. The gas mixture is a mixture of hydrogen gas and an additive gas. The additive gas includes at least either one of nitrogen atoms and oxygen atoms. When supplying the plasma supply unit 12 with plasma generation gas, the gas supply unit 13 adjusts the flow of the hydrogen gas and the flow of the additive gas in the gas mixture so that the flow ratio, which is the flow of the additive gas relative to the flow of the hydrogen gas, is 1/500 or greater. The plasma supply unit 12 generates plasma from the plasma generation gas supplied from the gas supply unit 13 and supplies plasma to the accommodation unit 11.

The gas supply unit 13 includes, for example, a hydrogen gas master controller and an additive gas master controller. Each master controller is connected to a tank for each gas located outside the substrate processing device 10. Preferably, the additive gas supplied by the gas supply unit 13 is, for example, at least one selected from a group consisting of nitrogen gas, oxygen gas, nitrogen monoxide gas, nitrogen dioxide gas, ammonia, and water (H₂O gas). Preferably, the additive gas is nitrogen gas or oxygen gas.

In addition to the gas mixture (hydrogen gas and additive gas), the gas supply unit 13 may supply a rare gas such as helium gas or argon gas to the plasma supply unit 12. The rare gas functions as assist gas that assists the generation of plasma from the gas mixture and the flow of the gas mixture. In this gas, the gas supply unit 13 may include an assist gas master controller.

The plasma supply unit 12 includes a plasma generation chamber 21, a plasma source 22, and a high-frequency power supply 23. The plasma generation chamber 21 is connected to the accommodation unit 11. The plasma generation chamber 21 includes a gas supply port 21a that is connected to the gas supply unit 13.

The plasma source 22 is arranged around the plasma generation chamber 21. The plasma source 22 is connected to the high-frequency power supply 23 that applies high-frequency voltage to the plasma source 22. As long as plasma can be generated from the gas mixture, the plasma source 22 may be an inductive coupling type plasma source or a magnetron type plasma source.

The plasma supply unit 12 generates plasma from the plasma generation gas by applying high-frequency voltage to the plasma source 22 with the high-frequency power supply 23 when the plasma generation chamber 21 is supplied with plasma generation gas. Then, the plasma supply unit 12 supplies plasma from the plasma generation chamber 21 to the accommodation unit 11.

The plasma generated from the plasma generation gas includes active species generated from the hydrogen gas. The active species are, for example, hydrogen ions and hydrogen radicals that are reducible.

The accommodation unit 11 includes a plasma supply port connected to the plasma generation chamber 21. In the accommodation unit 11, a diffuser 14 is arranged at a position opposing the plasma supply port. The plasma supplied from the plasma generation chamber 21 to the accommodation unit 11 strikes the diffuser 14. This diffuses the plasma inside the accommodation unit 11 in the radial direction of the plasma supply port.

A support 15 that supports the substrate S is arranged inside the accommodation unit 11. The support 15 may be, for example, a stage on which the substrate S is placed or a clamp that holds the periphery of the substrate S. The support 15 includes a heating mechanism (not illustrated) that heats the substrate S. For example, a known mechanism such as resistor heating is employed as the heating mechanism. The substrate S is supplied with plasma generated from the plasma generation gas. The substrate S includes, for example, a silicon layer, a conductive layer such as a metal layer formed from copper, and an oxide film formed on the surface of the conductive layer.

The accommodation unit 11 includes a discharge port 11a formed in the wall opposite to the plasma supply port. The discharge port 11a is connected to a discharge unit 16. The discharge unit 16 includes, for example, a pressure regulation valve that regulates the pressure inside the accommodation unit 11 and other various valves to reduce the pressure of the accommodation unit 11 to a predetermined pressure.

The substrate processing device 10 includes a control unit 30. The control unit 30 controls and drives the plasma supply unit 12 and the gas supply unit 13.

The control unit 30, for example, controls and drives the high-frequency power supply 23 to control and drive the plasma supply unit 12. For example, the control unit 30 controls the timing for supplying high-frequency power from the high-frequency power supply 23 to the plasma source 22 and the amount of power supplied by the high-frequency power supply 23.

The control unit 30, for example, controls and drives each master controller to control and drive the gas supply unit 13. For example, the control unit 30 controls the timing each master controller supplies gas to the plasma generation chamber 21 and the flow of the gas supplied to the plasma generation chamber 21.

For example, the control unit 30 controls and drives the gas supply unit 13 so that the supply of the plasma generation gas from the gas supply unit 13 to the plasma supply unit 12 is started when the substrate S is accommodated in the accommodation unit 11. Further, the control unit 30 controls and drives the plasma supply unit 12 so that plasma is generated over a predetermined time from the plasma generation gas supplied to the plasma supply unit 12.

Preferably, the control unit 30 controls the plasma supply unit 12 to start generating plasma after the flow of the plasma generation gas stabilizes (for example, after predetermined time elapses from when plasma generation gas is supplied).

In the present embodiment, the plasma generation gas corresponds to a first plasma generation gas. Further, hydrogen gas or gas obtained by combining hydrogen gas and a rare gas (i.e., gas excluding additive gas from first plasma generation gas) corresponds to a second plasma generation gas. The plasma generated from the first plasma generation gas corresponds to first plasma, and the plasma generated from the second plasma generation gas corresponds to second plasma.

The control unit 30 may drive and control the gas supply unit 13 to start supplying the second plasma generation gas after the first plasma is supplied to the accommodation unit 11. For example, the control unit 30 drives and controls the gas supply unit 13 to shift from a state in which gas including the additive gas (i.e., first plasma generation gas) is supplied to a state in which gas that does not include the additive gas (i.e., second plasma generation gas) is supplied by gradually decreasing the flow of the additive gas of the first plasma generation gas. Alternatively, the control unit 30 controls and drives the gas supply unit 13 to shift from a state in which gas including the additive gas (i.e., first plasma generation gas) is supplied to a state in which gas that does not include the additive gas (i.e., second plasma generation gas) is supplied by suddenly decreasing the flow of the additive gas of the first plasma generation gas. Further, the control unit 30 controls and drives the plasma supply unit 12 so that the second plasma is generated from the second plasma generation gas over a predetermined time.

During the generation of the second plasma, the control unit 30 may control the gas supply unit 13 and the high-frequency power supply 23 so that the generation of the second plasma is started by continuously supplying gas and high-frequency power subsequent to the generation of the first plasma. In this manner, the generation of the first plasma and the generation of the second plasma may be continuously performed. Alternatively, the control unit 30 may control the gas supply unit 13 and the high-frequency power supply 23 so that after the generation of the first plasma, the supply of high-frequency power is temporarily stopped while the supply of gas is continued and the supply of high-frequency power is subsequently restarted to start the generation of the second plasma. As another option, the control unit 30 may control the gas supply unit 13 and the high-frequency power supply 23 so that after the generation of the firs plasma, the supply of gas and the supply of high-frequency power are temporarily stopped at the same time and then subsequently restarted to start the generation of the second plasma.

[Substrate Processing Method]

A method for processing a substrate with the substrate processing device described above will now be described.

In the substrate processing method, a gas mixture is generated by mixing additive gas and hydrogen gas so that the flow which is the ratio of the additive gas relative to the flow of hydrogen gas is 1/500 or greater. Then, plasma is generated from the gas mixture or a gas combining the gas mixture and a rare gas. The plasma is applied to an oxide film formed on the substrate S to reduce the oxide film. The substrate S may be heated when plasma-processed. For example, the temperature of the substrate S when plasma-processed is 50° C. or greater, preferably, 150° C. or greater. There is no upper limit to the temperature of the substrate S when the substrate S is plasma-processed. The upper limit value only needs to be a temperature that can protect the substrate S, for example, 350° C. or less.

In the present example, the control unit 30 controls and drives the gas supply unit 13 so that the flow ratio of the gas mixture supplied by the gas supply unit 13 is 1/500 or greater. The control unit 30 drives and controls the high-frequency power supply 23 so that the high-frequency power supply 23 applies high-frequency voltage to the plasma source 22 to generate plasma from the plasma generation gas in the plasma generation chamber 21.

As a result, plasma is applied to the substrate S in accordance with the flow of gas formed in the accommodation unit 11 by the discharge unit 16 to reduce the oxide film of the substrate S.

In such a method and device, in contrast with when generating plasma from only hydrogen gas or from a gas mixture of hydrogen gas and rare gas, the additive gas in the gas mixture limits deactivation of the active species generated from the hydrogen gas. In the active species generated from the hydrogen gas, this increases the proportion of the active species that reach the oxide film. As a result, the reduction speed of the oxide film per consumed power is increased.

Further, in the substrate processing method, the second plasma generated from the second plasma generation gas may be applied to the substrate S after reducing the oxide film with the first plasma generated by the first plasma generation gas.

In this case, for example, the control unit 30 may control the gas supply unit 13 and the plasma supply unit 12 to execute the processes described below. First, the gas supply unit 13 supplies the plasma supply unit 12 with the first plasma generation gas and generates the first plasma from the plasma generation gas with the plasma supply unit 12. Further, the first plasma is supplied to the accommodation unit 11 to reduce the oxide film with the first plasma. Then, the supply of additive gas from the gas supply unit 13 to the plasma supply unit 12 is stopped to supply the plasma supply unit 12 with the second plasma generation gas and generate the second plasma from the second plasma generation gas with the plasma supply unit 12. The second plasma is supplied to the accommodation unit 11.

With such a method and device, subsequent to the reduction of the oxide film with the first plasma, the substrate S is supplied with the second plasma. Thus, after reducing the oxide film with the first plasma, at least either one of the oxygen atoms and the nitrogen atoms remaining in the substrate S can be removed from the substrate S with the second plasma.

### TEST EXAMPLES

Test examples will now be described with reference to FIGS. 2 to 10.

[Flow Ratio in Gas Mixture]

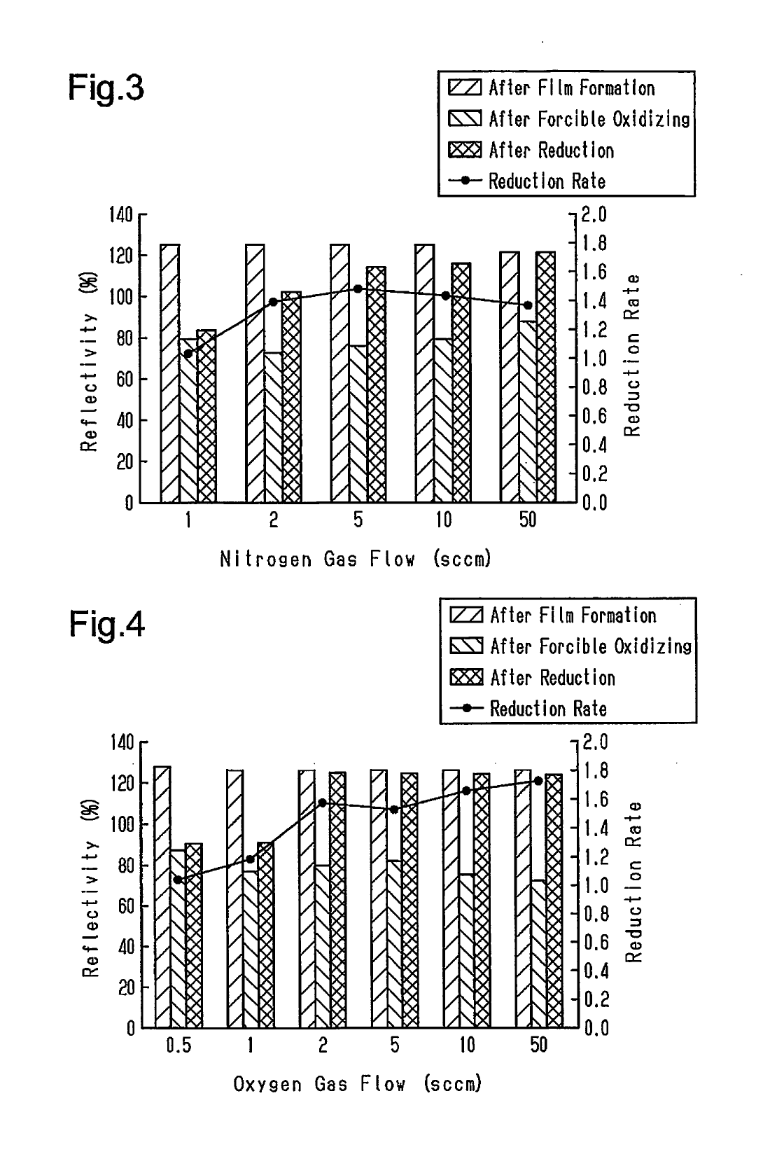

FIG. 2 is a graph illustrating the reduction rate when reducing the oxide film with only hydrogen gas. FIG. 3 is a graph illustrating the reduction rate when reducing the oxide film with the first plasma generation gas including nitrogen gas as the additive gas. FIG. 4 is a graph illustrating the reduction rate when reducing the oxide film with the first plasma generation gas that includes oxygen gas as the additive gas.

The method for calculating the reduction rate of the oxide film will now be described. A copper film was first formed on the surface of the substrate S, and the reflectivity of the copper film was measured using light having a wavelength of 436 nm. The copper film was forcibly oxidized by undergoing thermal oxidation to measure the reflectively of the forcibly oxidized copper film. Then, the oxide film formed on the surface of the copper film was reduced with the plasma generated from each gas, and the reflectivity of the reduced oxide film was measured. The ratio of the reflectivity of the reduced copper film relative to the reflectivity of the forcibly oxidized copper film was calculated.

The flow of the hydrogen gas, the flow of the argon gas, the pressure inside the accommodation unit 11, and the temperature of the substrate S were set to be the same regardless of whether or not additive gas was included. In the present example, the flow of the hydrogen was set to 1000 sccm, the flow of argon gas was set to 200 sccm, the pressure inside the accommodation unit 11 was set to 70 Pa, the processing time was set to 70 seconds, and the temperature of the substrate S was set to 150° C. Further, when reducing the oxide film with the first plasma generation gas including the gas mixture (hydrogen gas and additive gas) using microwaves as the plasma source 22, the high-frequency power supplied to the plasma source 22 was set to 500 W regardless of the type of additive gas.

As illustrated in FIG. 2, the reduction rate was 1.04 when supplying the plasma source 22 with 500 W of high-frequency power to generate hydrogen plasma. Further, the reduction rate was 1.10 when supplying the plasma source 22 with 1000 W of high-frequency power to generate hydrogen plasma.

As illustrated in FIG. 3, the reduction rate was 1.05 when the flow of nitrogen gas was 1 sccm and the flow ratio was 1/1000. The reduction rate was 1.40 when the flow of nitrogen gas was 2 sccm and the flow ratio was 1/500. The reduction rate was 1.50 when the flow of nitrogen gas was 5 sccm and the flow ratio was 1/200. The reduction rate was 1.45 when the flow of nitrogen gas was 10 sccm and the flow ratio was 1/100. The reduction rate was 1.38 when the flow of nitrogen gas was 50 sccm and the flow ratio was 1/20.

As illustrated in FIG. 4, the reduction rate was 1.03 when the flow of the oxygen gas was 0.5 sccm and the flow ratio was 1/2000. The reduction rate was 1.18 when the flow of the oxygen gas was 1 sccm and the flow ratio was 1/1000. The reduction rate was 1.57 when the flow of the oxygen gas was 2 sccm and the flow ratio was 1/500. The reduction rate was 1.52 when the flow of the oxygen gas was 5 sccm and the flow ratio was 1/200. The reduction rate was 1.66 when the flow of the oxygen gas was 10 sccm and the flow ratio was 1/100. The reduction rate was 1.72 when the flow of the oxygen gas was 50 sccm and the flow ratio was 1/20.

In this manner, in addition to when the additive gas was nitrogen gas, the reduction rate could also be significantly increased when the additive gas was oxygen gas as long as the flow ratio was 1/500 or greater compared with when reducing the oxide film with plasma that is generated from only hydrogen gas. In other words, the reduction speed of the oxide film per consumed power was increased.

As long as the flow ratio is 1/500 or greater, even if the high-frequency power supplied to the plasma source 22 is 500 W, the reduction rate is higher than when generating plasma from only hydrogen gas by supplying the plasma source 22 with 1000 W or high-frequency power. Accordingly, by mixing additive gas to the hydrogen gas, the reduction rate of the oxide film can be increased more effectively than when simply increasing the high-frequency power supplied to the plasma source 22.

When the additive gas is nitrogen gas, in order to increase the reduction speed of the oxide film per consumed power while decreasing the nitrogen atoms remaining in the substrate subsequent to reduction, it is preferable that the flow ratio be 1/500 or greater and 1/10 or less, more preferable that the flow ratio be 1/500 or greater and 1/20 or less, and further preferable that the flow ratio be 1/500 or greater and 1/100 or less.

When the additive gas is oxygen gas, in order to increase the reduction speed of the oxide film per consumed power while decreasing the oxygen atoms remaining in the substrate subsequent to reduction, it is preferable that the flow ratio be 1/500 or greater and 1/10 or less and more preferable that the flow ratio be 1/500 or greater and 1/20 or less.

[Luminescence Intensity of Hydrogen Plasma]

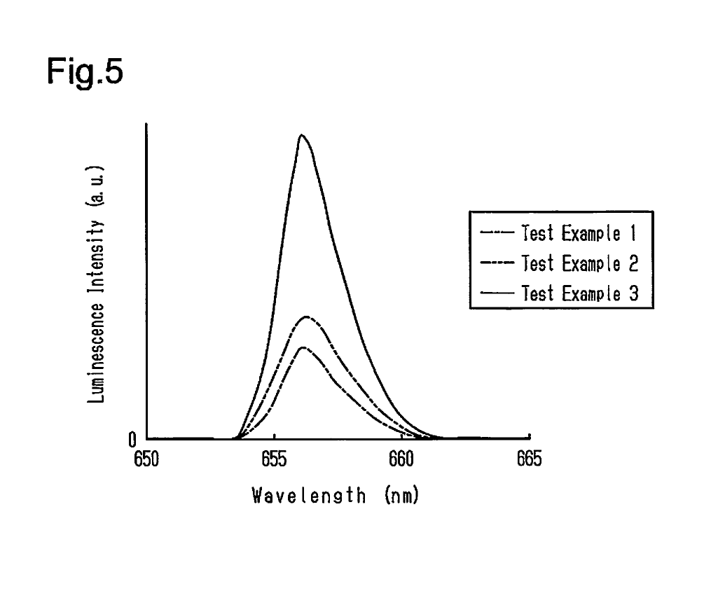

With reference to FIG. 5, the luminescence intensity of the hydrogen plasma will now be described. FIG. 5 is a graph illustrating the luminescence intensity of the hydrogen plasma measured by a plasma luminescence monitor in test examples 1 to 3, which will be described below. In each of test examples 1 to 3, microwaves were used as the plasma source 22.

### Test Example 1

In test example 1, hydrogen gas was used as the plasma generation gas to generate plasma. In test example 1, the flow of hydrogen gas was set to 1000 sccm, the flow of argon gas was set to 200 sccm, and the high-frequency power supplied to the plasma source 22 was set to 500 W.

### Test Example 2

In test example 2, first plasma generation gas including nitrogen gas as the additive gas was used to generate plasma. In test example 2, the flow of the hydrogen gas was set to 1000 sccm and the flow of nitrogen gas was set to 2 sccm to set the flow ratio of 1/500. Further, the flow of argon gas was set to 200 sccm, and the high-frequency power supplied to the plasma source 22 was set to 500 W.

### Test Example 3

In test example 3, hydrogen gas was used as the plasma generation gas to generate plasma. In test example 3, the flow of hydrogen gas was set to 1000 sccm, the flow of argon gas was set to 200 sccm, and the high-frequency power supplied to the plasma source 22 was set to 1000 W.

As illustrated in FIG. 5, the luminescence intensity of test example 2 was greater than the luminescence intensity of test example 1, and the luminescence intensity of test example 3 was greater than the luminescence intensity of test example 2. Further, the difference between the luminescence intensity of test example 2 and the luminescence intensity of test example 3 was greater than the difference between the luminescence intensity of test example 1 and the luminescence intensity of test example 2.

As illustrated in FIG. 2 and described above, the reduction rate under the condition of test example 1 was 1.04, and the reduction rate under the condition of test example 3 was 1.10. In contrast, as illustrated in FIG. 3 and described above, the reduction rate under the condition of test example 2 was 1.40. Thus, the reduction rate in test example 2 is not increased because of the amount of active species in the plasma generated from the hydrogen gas being greater than test example 1. Rather, in test example 2, the additive gas (nitrogen gas) limited recoupling of hydraulic radicals and decreased deactivation of the active species. This increased the amount of the active species that reached the oxide film of the substrate S. As a result, the reduction rate in test example 2 was higher than the reduction rate in test example 1 (and test example 3).

[Surface Analysis Conducted Through SIMS]

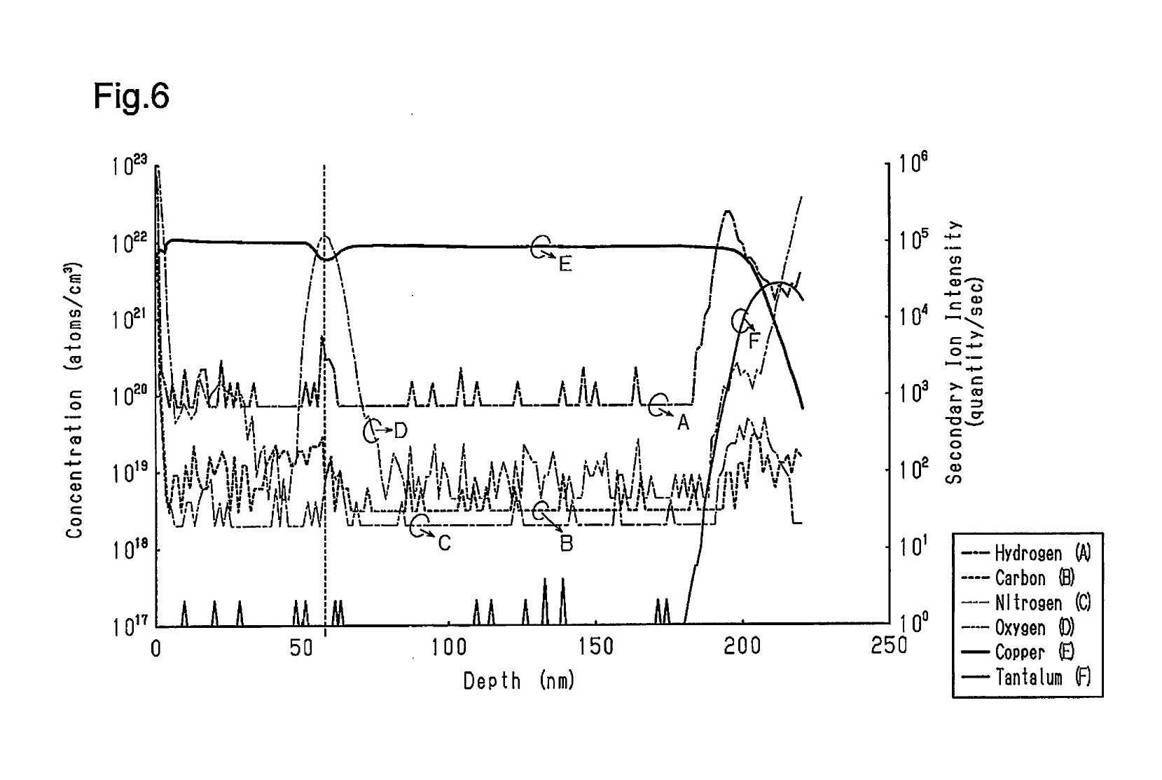

With reference to FIGS. 6 to 10, the results of a surface analysis conducted by performing SIMS on analysis substrates of following test examples 4 to 8 will now be described.

### Test Example 4

A laminate was obtained by forming a tantalum layer having a thickness of 5 nm on the surface of a substrate and forming a first copper layer having a thickness of 150 nm on the surface of the tantalum layer. After leaving the laminate in the atmosphere in a still state for ten days, a second copper layer having a thickness of 50 nm was formed on the first copper layer to obtain the analysis substrate of test example 4.

### Test Example 5

The analysis substrate of test example 5 was obtained in the same manner as test example 4 except in that a reduction process was performed on the laminate prior to the formation of the second copper layer. In the reduction process of test example 5, the flow of hydrogen gas was set to 1000 sccm, the flow of argon gas was set to 200 sccm, the flow of oxygen gas serving as the additive gas was set to 2 sccm, the pressure inside the accommodation unit 11 was set to 70 Pa, the high-frequency power was set to 500 W, the processing time was set to 10 seconds, and the temperature of the substrate S was set to 150° C. Microwaves were used as the plasma source 22.

### Test Example 6

The analysis substrate of test example 6 was obtained in the same manner as test example 5 except in that the processing time of the reduction process was set to 60 seconds.

### Test Example 7

The analysis substrate of test example 7 was obtained in the same manner as test example 6 except in that nitrogen gas was used as the additive gas in the reduction process.

### Test Example 8

The analysis substrate of test example 8 was obtained in the same manner as test example 5 except in that the surface of the first copper layer was processed with the second plasma generation gas after reducing the surface of the first copper layer under the same conditions as test example 5 and before forming the second copper layer. In the step for processing the surface of the first copper layer with the second plasma generation gas, the flow of the hydrogen gas was set to 1000 sccm, the flow of argon gas was set to 200 sccm, the pressure inside the accommodation unit 11 was set to 70 Pa, the high-frequency power was set to 500 W, and the processing time was set to 60 seconds.

[Analysis Results]

As illustrated in FIG. 6, in the analysis substrate of test example 4, the concentration of oxygen atoms in the surface of the first copper layer was 1.5×10²² atoms/cm³, the concentration of nitrogen atoms was 1.0×10¹⁹ atoms/cm³, the concentration of carbon atoms was 2.0×10¹⁹ atoms/cm³, and the concentration of hydrogen atoms was 5.0×10²⁰ atoms/cm³.

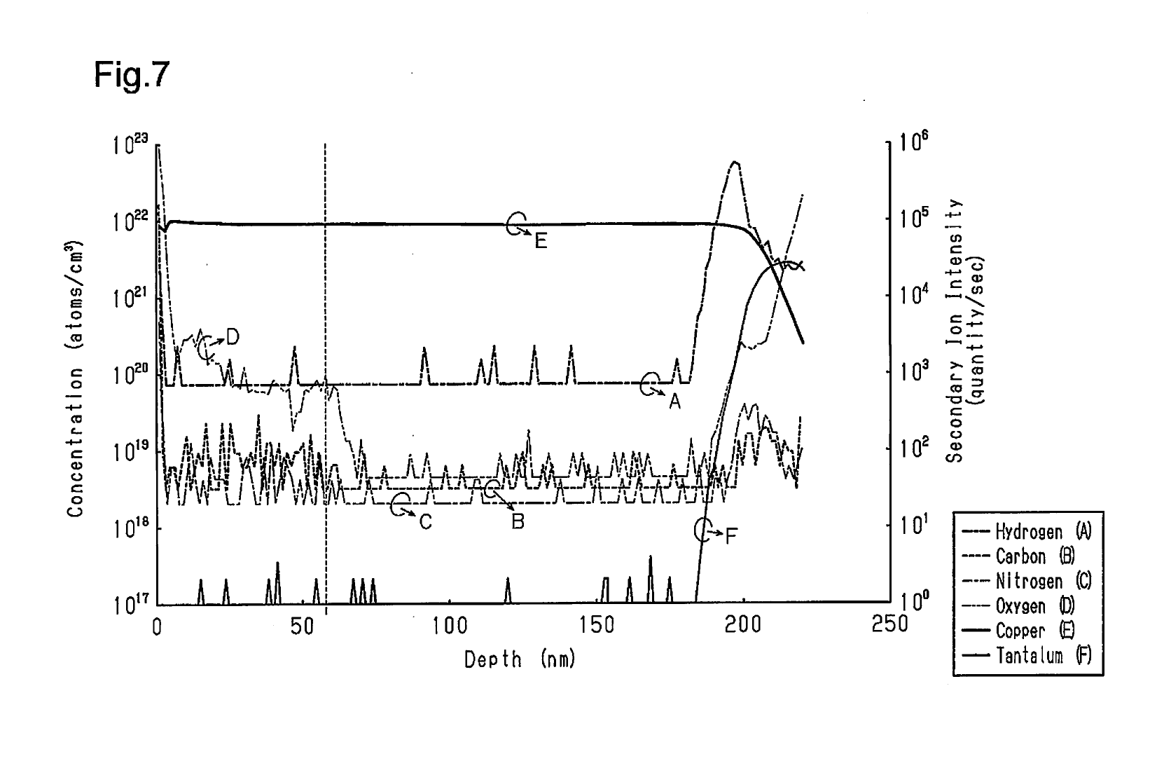

As illustrated in FIG. 7, in the analysis substrate of test example 5, the concentration of oxygen atoms in the surface of the first copper layer was 8.0×10¹⁹ atoms/cm³. Further, the concentration of nitrogen atoms, the concentration of carbon atoms, and the concentration of hydrogen atoms were each approximately the same as the lower limit detection value. In other words, there were substantially no nitrogen atoms, carbon atoms, and hydrogen atoms remaining in the surface of the first copper layer.

That is, in the reduction process of test example 5, although it was possible to reduce the oxide film formed on the surface of the first copper layer, oxygen atoms remained in the surface of the first copper layer. Further, in the reduction process of test example 5, the oxide film was reduced, and nitrogen atoms, carbon atoms, and hydrogen atoms were removed from the surface of the first copper layer.

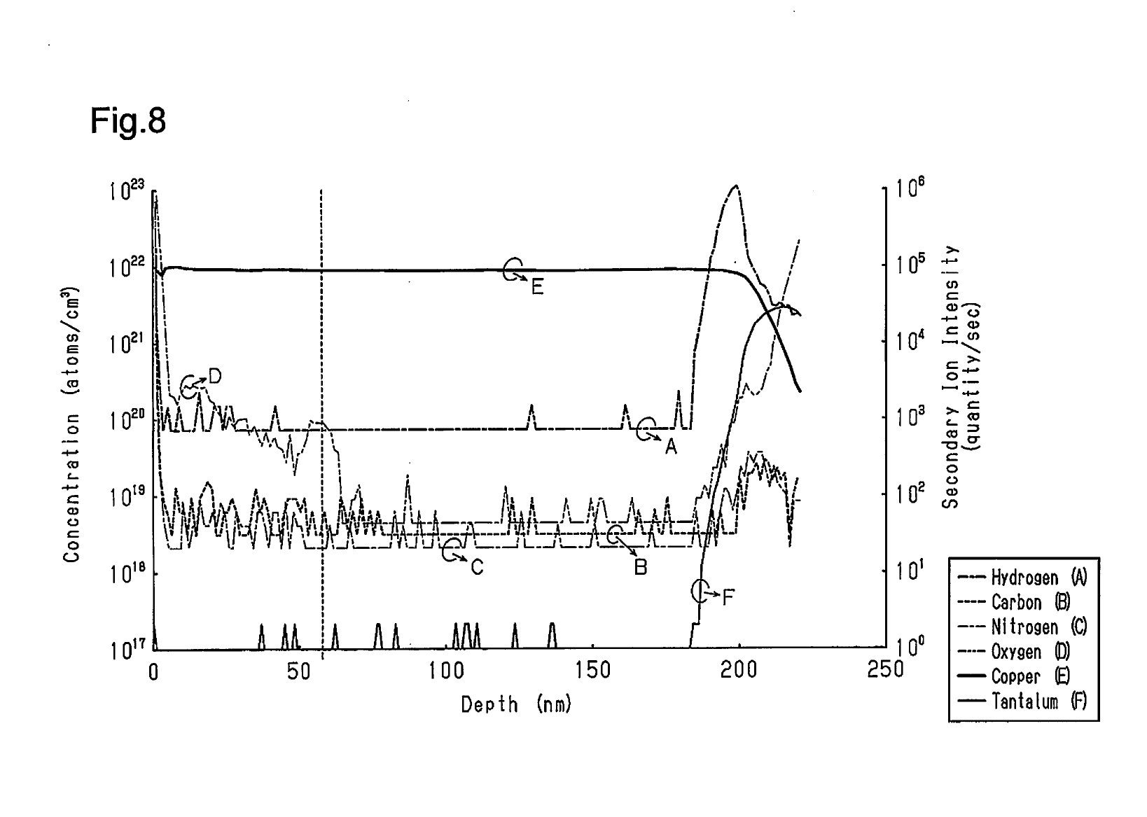

As illustrated in FIG. 8, in the analysis substrate of test example 6, the concentration of oxygen atoms in the surface of the first copper layer was 9.0×10¹⁹ atoms/cm³. Further, the concentration of nitrogen atoms, the concentration of carbon atoms, and the concentration of hydrogen atoms were each approximately the same as the lower limit detection value. In other words, there were substantially no nitrogen atoms, carbon atoms, and hydrogen atoms remaining in the surface of the first copper layer.

That is, in the reduction process of test example 6, although it was possible to reduce the oxide film formed on the surface of the first copper layer to approximately the same level as test example 5, oxygen atoms remained in the surface of the first copper layer. Further, in the reduction process of test example 6, the oxide film was reduced, and nitrogen atoms, carbon atoms, and hydrogen atoms were removed from the surface of the first copper layer.

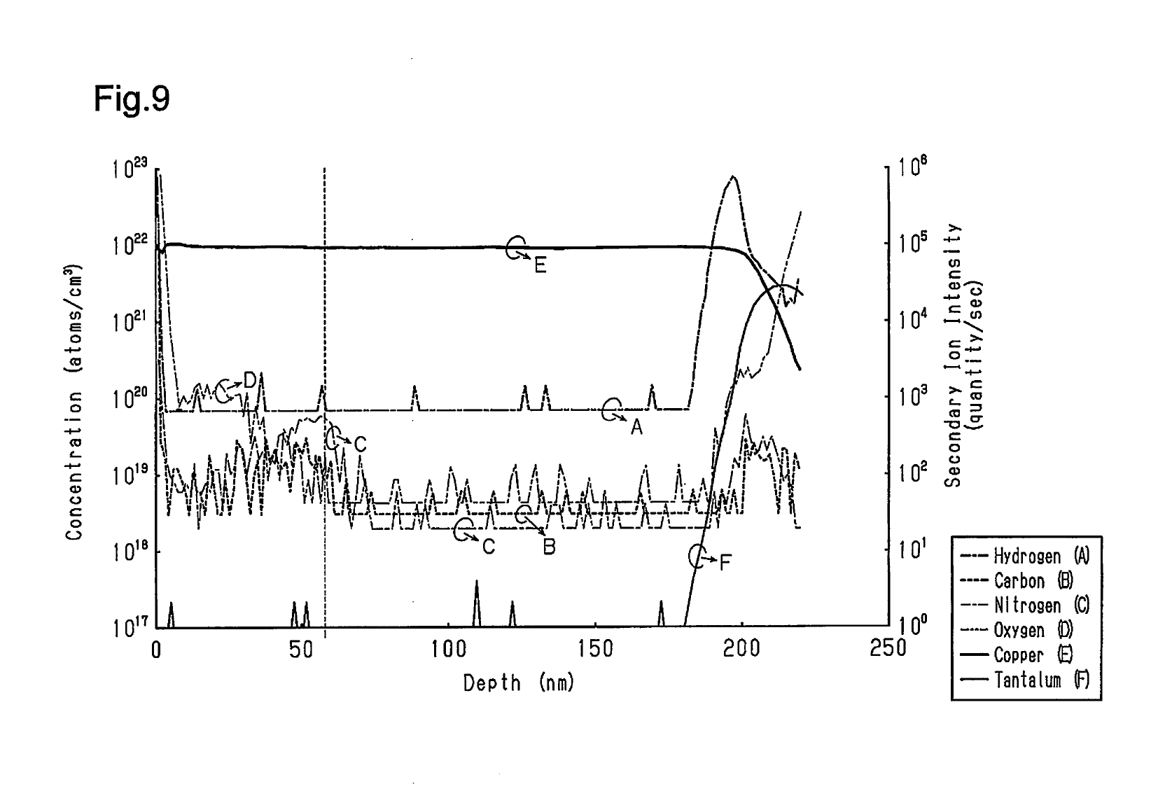

As illustrated in FIG. 9, in the analysis substrate of test example 7, the concentration of oxygen atoms in the surface of the first copper layer was approximately the same level as the lower limit detection value. Further, the concentration of nitrogen was 6.0×10¹⁹ atoms/cm³, the concentration of carbon atoms was 2.0×10¹⁹ atoms/cm³, and the concentration of hydrogen atoms was approximately the same level as the lower limit detection value. In other words, there were substantially no oxygen atoms and hydrogen atoms remaining in the surface of the first copper layer.

That is, in the reduction process of test example 7, although it was possible to reduce the oxide film formed on the surface of the first copper layer, nitrogen atoms remained in the surface of the first copper layer. Further, in the reduction process of test example 7, the oxide film was reduced, and hydrogen atoms were removed from the surface of the first copper layer.

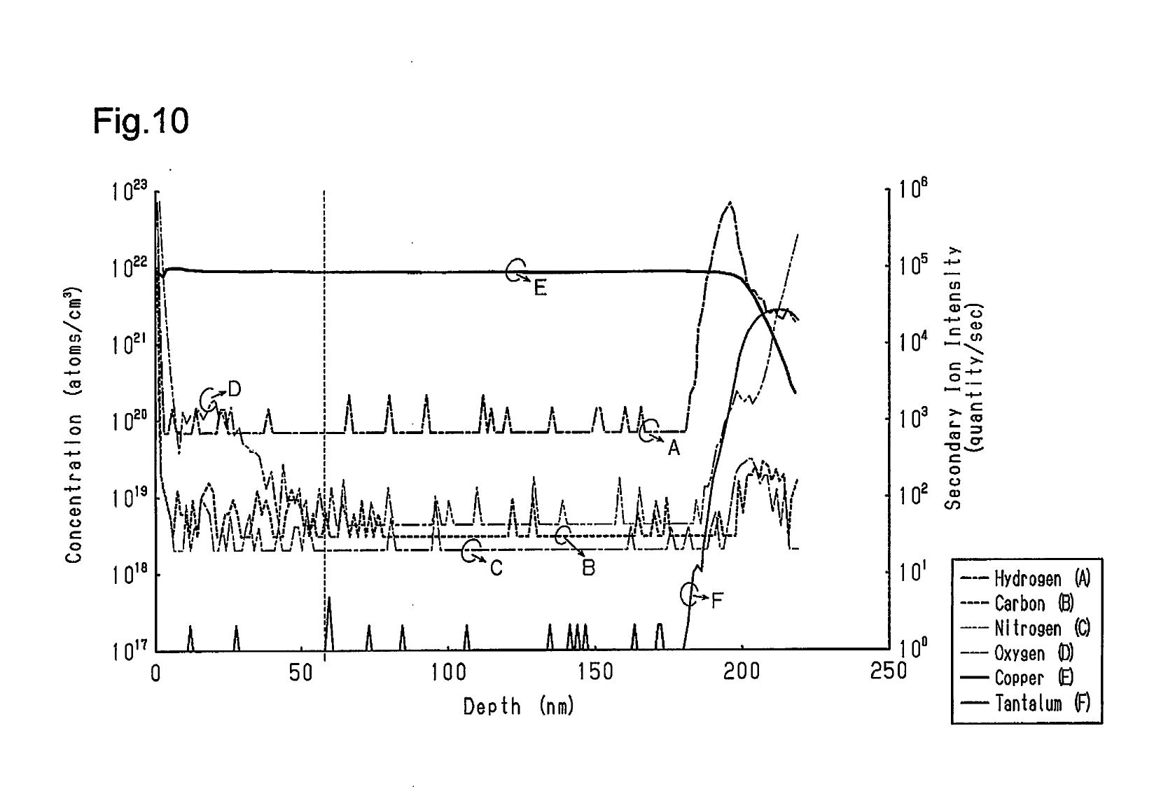

As illustrated in FIG. 10, in the analysis substrate of test example 8, the concentration of oxygen atoms, the concentration of nitrogen atoms, the concentration of carbon atoms, and the concentration of hydrogen atoms in the surface of the first copper layer were all approximately the same level as the lower limit detection value. In other words, there were substantially no oxygen atoms, nitrogen atoms, carbon atoms, and hydrogen atoms remaining in the surface of the first copper layer.

That is, in the reduction process of test example 8, the oxygen atoms remaining in the surface of the first copper layer after the oxide film was reduced with the plasma generated from the first plasma generation gas were removed by processing the first copper layer with the plasma generated from the second plasma generation gas.

In this manner, reduction of the oxide film with the plasma generated from the first plasma generation gas including oxygen gas, which serves as the additive gas, reduces the oxide film. The oxygen atoms in the additive gas can be removed from the surface of the substrate by processing the oxide film with the plasma of the second plasma generation gas after reducing the oxide film with the first plasma generation gas. Although not described here, when processing the oxide film with the plasma of the second plasma generation gas after reducing the oxide film with the first plasma generation gas that includes nitrogen gas as the additive gas, the nitrogen atoms in the additive gas can be removed from the surface of the substrate.

The substrate processing method and the substrate processing device of the present embodiment have the advantages listed below.

(1) In contrast with when plasma is generated from only hydrogen gas, the generation of plasma from the gas mixture of hydrogen gas and additive gas limits deactivation of active species, which are generated from the hydrogen gas, in a preferred manner. This increases the ratio of the active species that reach the oxide film in the active species generated from the hydrogen gas and consequently increases the reduction speed of the oxide film per consumed power.

(2) As long as the additive gas is oxygen gas and the flow ratio is 1/10 or less, deactivation of active species is limited, and the oxygen atoms in the plasma that remain in the substrate are limited.

(3) As long as the additive gas is nitrogen gas and the flow ratio is 1/10 or less, deactivation of active species is limited, and the nitrogen atoms in the plasma that remain in the substrate are reduced.

(4) The substrate S is processed with the second plasma after reducing the oxide film with the first plasma. This allows for the removal of at least either one of the oxygen atoms and nitrogen atoms remaining in the substrate S because of the use of the first plasma.

The above embodiments may be modified as described below.

When the additive gas is nitrogen gas and the oxide film on the substrate S can be reduced, the flow ratio may be greater than 1/10. In this case, the upper limit value of the flow ratio in gas mixture is selected from a range in which the nitrogen atoms remaining in the surface of the substrate S do not affect the processing result of a subsequent process.

When the additive gas is oxygen gas and the oxide film on the substrate S can be reduced, the flow ratio may be greater than 1/10. In this case, the upper limit value of the flow ratio in gas mixture is selected from a range in which the oxygen atoms remaining in the surface of the substrate S do not affect the processing result of a subsequent process.

As long as the flow ratio is 1/500 or greater, the flow of the hydrogen gas does not have to be 1000 sccm. In this case, the upper limit value of the flow ratio in the gas mixture is selected from a range in which the nitrogen atoms and/or the oxygen atoms remaining in the surface of the substrate S do not affect the processing result of a subsequent process.

The plasma supply unit 12 is not limited to a configuration in which plasma is generated outside the accommodation unit 11 and supplied to the accommodation unit 11. The plasma supply unit 12 may be configured to generate plasma inside the accommodation unit 11. In such a configuration, the plasma supply unit 12 only needs to include, for example, the accommodation unit 11, an inductively coupled plasma (ICP) coil arranged around the accommodation unit 11, and a power supply that applies high-frequency voltage to the ICP coil.

1. A substrate processing method comprising:
generating a gas mixture by mixing hydrogen gas and an additive gas;
generating plasma from the gas mixture or a gas combining the gas mixture and a rare gas; and
reducing an oxide film formed on a substrate with the plasma, wherein
the additive gas includes at least either one of nitrogen atoms and oxygen atoms, and
the generating a gas mixture includes mixing the additive gas and the hydrogen gas so that a flow ratio that is a ratio of a flow of the additive gas relative to a flow of the hydrogen gas is 1/500 or greater.

2. The substrate processing method according to claim 1, wherein the additive gas is oxygen gas, and the flow ratio is set to 1/10 or less.

3. The substrate processing method according to claim 1, wherein the additive gas is nitrogen gas, and the flow ratio is set to 1/10 or less.

4. The substrate processing method according to claim 1, wherein the reducing an oxide film includes using the plasma as first plasma to reduce the oxide film, the substrate processing method further comprising:
generating second plasma from the hydrogen gas or a gas combining the hydrogen gas and the rare gas by stopping supply of the additive gas after reducing the oxide film with the first plasma, and
applying the second plasma to the substrate.

5. A substrate processing device comprising:
an accommodation unit that accommodates a substrate;
a gas supply unit that supplies plasma generation gas; and
a plasma supply unit that generates plasma from the plasma generation gas supplied by the gas supply unit and supplies the plasma to the accommodation unit, wherein
the plasma generation gas is a gas mixture of hydrogen gas and an additive gas or a gas combining the gas mixture and a rare gas,
the additive gas includes at least either one of nitrogen atoms and oxygen atoms, and
the gas supply unit is configured to supply the plasma supply unit with the plasma generation gas so that a flow ratio that is a ratio of a flow of the additive gas relative to a flow of the hydrogen gas is 1/500 or greater.

6. The substrate processing device according to claim 5, wherein the gas supply unit is capable of supplying the plasma generation gas as a first plasma generation gas and capable of supplying the hydrogen gas or a gas combining the hydrogen gas and the rare gas as a second plasma generation gas, the substrate processing device further comprising:
a control unit configured to control the plasma supply unit and the gas supply unit so as to execute processes including
supplying the first plasma generation gas from the gas supply unit to the plasma supply unit,
generating first plasma from the first plasma generation gas with the plasma supply unit and supplying the first plasma to the accommodation unit,
supplying the second plasma generation gas from the gas supply unit to the plasma supply unit by stopping supply of the additive gas after supplying the first plasma to the accommodation unit, and
generating second plasma from the second plasma generation gas with the plasma supply unit and supplying the second plasma to the accommodation unit.
